(19) United States
(12) Patent Application Publication
(10) Pub. No.: US 2005/0286417 A1
(43) Pub. Date: Dec. 29, 2005

(54) Device and method of controlling and providing content over a network

(75) Inventors: Cheol-bong An, Gyeonggi-do (KR); In-hwan Kim, Gyeonggi-do (KR); Alexandre Magzoumov, Gyeonggi-do (KR); Ju-han Lee, Gyeonggi-do (KR); Ho-jeong You, Gyeonggi-do (KR); Jun-hae Choi, Gyeonggi-do (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/158,962

(22) Filed: Jun. 23, 2005

(30) Foreign Application Priority Data
Jun. 24, 2004 (KR) 10-2004-0047672

(51) Int. Cl. G08C 15/00; H04L 12/26; H04J 3/16; H04L 12/56; H04L 12/28; G01R 31/08; G06F 11/00; H04J 3/14; H04J 1/16; H04L 1/00; H04J 3/22

(52) U.S. Cl. 370/229; 370/465

(57) ABSTRACT

A device and method of controlling content transmission, and a device and method of providing content. The method of controlling content over a network includes generating a control command using a stateless protocol so that an AV content providing device controls transmission of an AV content using a connectionless protocol and transmitting the generated control command to the AV content providing device. Accordingly, when AV content is transmitted through RTP over a network, the content is controlled by a stateless protocol such as HTTP instead of a state protocol such as RTSP. Thus, RTP is easily supported by an effective content control method.

### CROSS-REFERENCE TO RELATED APPLICATION

This application claims the priority of Korean Patent Application No. 10-2004-0047672, filed on Jun. 24, 2004, in the Korean Intellectual Property Office, the disclosure of which is incorporated herein in its entirety by reference.

### BACKGROUND OF THE INVENTION

1. Field of the Invention

The present invention relates to content control, and more particularly, to a device for and a method of controlling content transmission over a network, and a device for and a method of providing content over a network.

2. Description of the Related Art

With the advance of the digital age, there are more opportunities to connect the digital products around us. A number of digital products such as DVD players, cable set top boxes (STB), digital video cassette recorders (DVCR), digital televisions (DTV), and personal computers (PC) can be connected in a single network. These various digital products are connected over a network and a home network standard to control the digital products has been established by the Digital Home Working Group (DHWG).

Home network technology can be classified mainly into three worlds. These include a PC Internet world, a mobile world, and a Consumer Electronics (CE) broadcast world.

FIG. 1 is a view for explaining a conventional home network environment according to the definition by the DHWG.

The PC Internet world 100 includes PCs 101, game consoles 102, printers 103, digital imaging devices 104, digital music devices 105, wireless monitors 106, and others.

The mobile world 110 includes laptop computers 111, multimedia mobile phones 112, PDAs 113, and others. They provide users with freedom of movement into and out of the home network.

The CE broadcast world 120 includes TV monitors 121, traditional consumer electronics 122 such as personal video recorders (PVR), tuners, set top boxes (STB), stereo sets 123, and others.

Consumers want to connect devices from the three domains together at home. Therefore, a research on the home network is required to attain interoperability between these digital worlds.

The digital home consists of networks of CE, mobile, and PC devices that cooperate with each other for simple, transparent and seamless interoperability. These networks are based on EP networking protocols and Universal Plug and Play (UPnP) technology.

Media management and control based on UPnP audio/video AV technology enables devices and applications to identify, manage, and distribute media content in the home network, and to transfer the media content to mobile devices.

UPnP is a peer-to-peer network architecture that can be used to connect, for example, intelligent appliances, wireless devices, and PCs. It is designed to provide usable, adaptable and standard-based connectivity to a small network in, for example, a home or a small business. The UPnP AV architecture defines the general interaction between UPnP devices and an associated UPnP control point. The UPnP architecture allows devices to support content in any format and over any transport protocol. UPnP devices include TVs, video cassette recorders (VCR), compact disc (CD) players, digital video disc (DVD) players, set top boxes, stereo systems, MP3 players, still image cameras, camcorders, and PCs. Further, the AV architecture allows the devices to support content in different formats such as MPEG2, MPEG4, JPEG, MP3, BMP, and Windows media architecture (WMA), and other transport protocols such as IEEE-1394, HTTP, RTP, and TCP/IP.

Most UPnP AV scenarios involve transmission of content such as movies, music, and pictures, from one device to another device. An AV control point cooperates with two or more UPnP devices which are a “source” and a “sink”. While the control point regulates and synchronizes the operations of the two devices, the devices communicate with each other using a non-UPnP (out-of-band) communication protocol. The control point uses UPnP to initialize and set the two devices, so that the desired content can be transferred to one device from the other device. However, since the content is sent using an out-of-band transport protocol, the control point is not directly involved in substantial content transmission.

The UPnP AV specification classifies logical devices into two types in the home network-media servers and media renderers.

The media servers have contents that users want to render on the media renderer. The users search and select contents from the media server and interact with a control point user interface UI to select a desired media renderer. The media servers may include a plurality of contents or access the contents. The media servers access the contents and transfer the contents to other devices over a network by using a predetermined transport protocol. The content is transferred using a transport protocol and a data format which the media servers and the media renderers can understand. The media servers may include VCRs, CD/DVD players, cameras, camcorders, set top boxes, satellite receivers, audio tape players, etc.

The media renderers receive content from the media servers over a network. The media renderers may include TVs, stereo systems, MP3 players, and electronic picture frames.

The control point regulates and manages operations of the media server and the media renderer, as designated by the user, to perform operations such as playing what the user wants. Further, the control point provides the UI so that the user can control the operations of the devices. The control point may be a TV or a wireless PDA device having a general remote controller. In addition, the control point may control the flow of content by invoking various AV transfer actions such as stop, pause, fast forward, rewind, and skip according to the request of the user.

FIG. 2 is a diagram of a conventional UPnP system configuration.

Referring to FIG. 2, the UPnP system includes a control point 200, a source device 210, and a sink device 220.

The control point 200 controls the source device 210 and the sink device 220 and detects the states thereof using a simple object access protocol (SOAP) command.

The source device 210, which functions as a media server, provides AV content to the sink device 220, and receives commands from the control point 200 to provide necessary information on the content. Also, the source device 210 receives a real-time streaming protocol (RTSP) command from the sink device 220 and transfers data over a real-time protocol (RTP).

The sink device 220, which functions as a media renderer, consumes AV content, receives commands from the control point 200 and performs necessary operations. For example, after receiving a play command from the control point 200, the sink device performs setup and play commands by using a RTSP protocol. The setup command of the RTSP specifies a transfer mechanism to be used. PLAY is a method of ordering a server to start data transmission using the mechanism specified by SETUP.

RTSP will now be briefly.

Most Internet multimedia users want to control continuous playback of media by stopping playback, seeking a next or previous clip, fast forwarding, or rewinding. Such operations are similar to the operations performed by a video cassette recorder and a compact disc (CD) players. To enable the users to control the playback, a media player and a server need a protocol for exchanging play control information, and that protocol is the real-time streaming protocol (RTSP) defined in RFC (Request for Comments) 2326. RTSP is a so-called out-of-band protocol, and an RTSP message is sent using either the Transport Control Protocol (TCP) or the User Data Protocol (UDP). The RTSP is a protocol that enables media players to control transmission of a media stream. RTSP does not define how audio and video is encapsulated into packets for transmission over a network. However, a real-time transport protocol (RTP) or a certain private protocol can define how streaming data is encapsulated.

HTTP is an asymmetric protocol where a client issues requests and a server responds. In RTSP, both a media client and a media server can issue requests. Real-time media generally uses RTP as a transport protocol, but RTSP is not tied with RTP.

RTP (Real-Time Transport Protocol) will be briefly explained in the following.

Before transferring AV data units to a transport layer on the transmit side of a multimedia application, sequence numbers and timestamps are attached to the AV data units. Since most all multimedia networking applications can make use of sequence numbers and timestamps, it is convenient to have a standardized packet structure that includes fields for AV data, sequence numbers and timestamps, as well as other potentially useful fields. RTP, defined in RFC 1889, is such a standard. In general, RTP is executed on a User Datagram Protocol (UDP). The AV data units generated by the transmit side of the multimedia application are encapsulated into RTP packets. The RTP packets are reencapsulated into UDP segments.

The control point 200 executes commands to obtain content information from the source device 210, and provides the sink device 220 with the protocol information and content uniform resource locator (URL) which is sent together with a play command to play the necessary content. If the protocol to be transmitted is HTTP, the sink device 220 obtains data from the source device 210 by using an HTTP Get method, or if the protocol to be transmitted is RTP, the sink device 220 executes setup and play commands with respect to the source device 210 by using an RTSP command, and then using RTP, the source device 210 transfers the content data specified in the commands.

As known from the above operations, when data is transmitted using RTP, counterpart devices should be controlled by using the RTSP protocol. However, the control method of the RTSP protocol is complicated, thereby making it difficult to implement the RTSP protocol. Hence, a method of controlling counterpart devices by using a simple protocol is required.

In particular, if a device were to include HTTP protocol capable of transmitting both commands and data, it would be preferable to use the HTTP protocol instead of another protocol. Specially, it would be better than using RTSP to transfer a command for receiving data using RTP.

### SUMMARY OF THE INVENTION

The present invention provides a device for and a method of simply controlling AV content, and a device for and a method of providing content.

According to an exemplary embodiment of the present invention, there is provided a method of controlling content over a network comprising: generating a control command using a stateless protocol so that an AV content providing device controls transmission of an AV content using a connectionless protocol and transmitting the generated control command to the AV content providing device.

A real-time transport protocol (RTP) may be used as the connectionless protocol and a hypertext transfer protocol (HTTP) may be used as the stateless protocol. The control command using the stateless protocol may include information about a port to which the AV content is sent using the connectionless protocol. Further, the control command using the stateless protocol may include information about a transport system in which the AV content is transmitted using the connectionless protocol. The transport system may include unicast or multicast. Release of connection based on the stateless protocol may stop the transmission of the AV content using the connectionless protocol.

According to another embodiment of the present invention, there is provided a method for providing content over a network comprising: receiving a control command using a stateless protocol from an AV content controlling device in order to control transmission of an AV content; and transmitting the AV content to the AV content controlling device by using a connectionless protocol in response to the control command.

According to still another embodiment of the present invention, there is provided a device for controlling content over a network comprising: an AV transmitting service unit generating a control command using a stateless protocol and transmitting the generated control command so that an AV content providing device can control an AV content transmission.

According to yet another embodiment of the present invention, there is provided a device for providing content over a network comprising: an AV transmitting service unit receiving a control command using a stateless protocol from an AV content controlling device that controls transmission of an AV content and interpreting the received control command; and a transferring unit sending the AV content to the AV content controlling device based on the interpreted information by using a connectionless protocol.

### BRIEF DESCRIPTION OF THE DRAWINGS

The above and other features and advantages of the present invention will become more apparent by describing in detail exemplary embodiments thereof with reference to the attached drawings in which:

FIG. 1 is a view showing a conventional home network environment according to the digital home working group (DHWG);

FIG. 2 is a diagram of a conventional system configuration composed of a control point, a source device and a sink device;

FIG. 3 is a diagram of a system composed of a control point, a source device and a sink device according to an embodiment of the present invention;

FIG. 4 is a block diagram of a configuration of a source device according to an embodiment of the present invention;

FIG. 5 is a block diagram of a sink device configuration according to an embodiment of the present invention;

FIG. 6 is a flowchart of a normal play/stop operation according to an embodiment or the present invention;

FIG. 7 is an example of a message for getting the content descriptor shown in the flowchart of FIG. 6;

FIG. 8 is an example of a message including the content descriptor shown in the flowchart of FIG. 6;

FIG. 9 is an example of the HTTP POST PLAY command shown in the flowchart of FIG. 6;

FIG. 10 is a flowchart for explaining the operations involved when RTP transmission stops due to source-sink connection loss according to an embodiment of the present invention; and

FIG. 11 is a flowchart for explaining the operations involved in stopping RTP transmission by an HTTP PAUSE command according to an embodiment of the present invention.

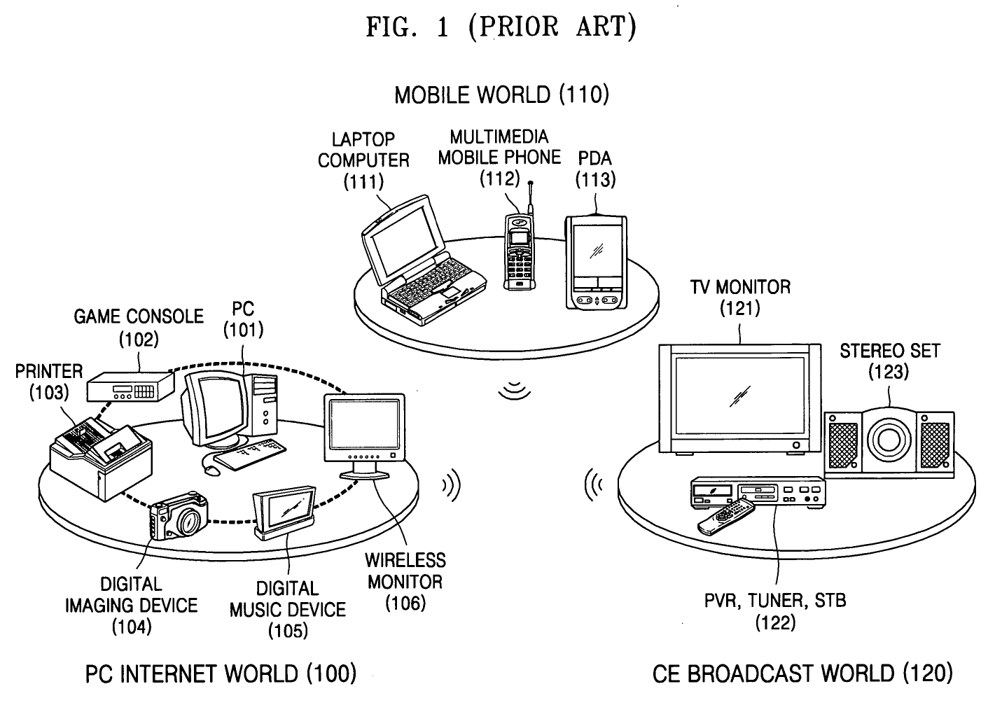

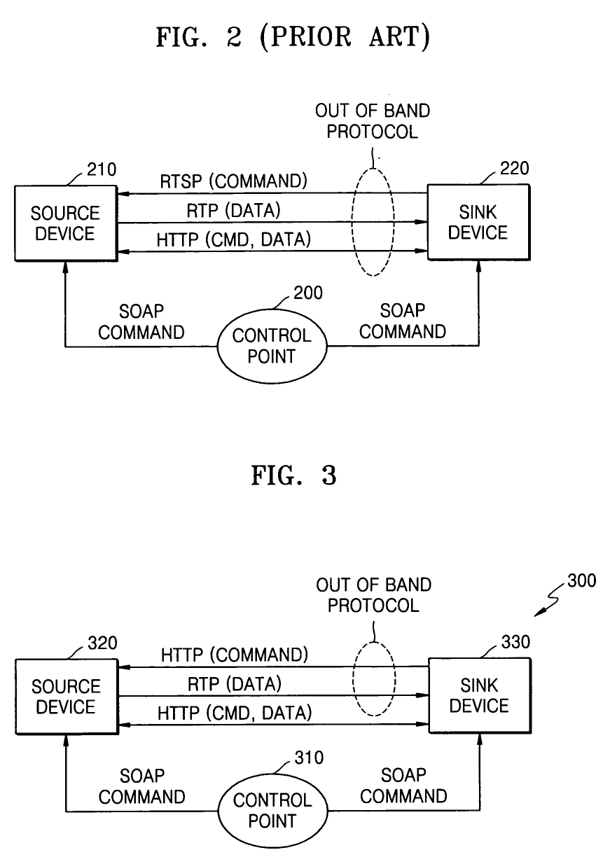

### DETAILED DESCRIPTION OF THE PREFERRED EMBODIMENTS

The present invention will now be described more fully with reference to the accompanying drawings, in which preferred exemplary embodiments of the invention are shown. Throughout the drawings, like reference numerals are used to refer to like elements.

FIG. 3 is a diagram showing the configuration of a universal plug and play (UPnP) system in accordance with an exemplary embodiment of the present invention.

Referring to FIG. 3, the UPnP system 300 includes a control point 310, a source device 320, and a sink device 330.

The control point 310 controls the source device 320 and the sink device 330 and detects states thereof, using a simple object access protocol (SOAP) command.

The source device 320 receives commands from the control point 310, provides necessary information to the control point, receives commands from the sink device 330 and provides audio/video AV content thereto. In particular, according to an exemplary embodiment of the present invention, the source device 320 receives a content control command of a stateless protocol such as the hypertext transfer protocol HTTP, from the sink device 330, and then transfers AV content to the sink device 330 using a connectionless protocol such as the real-time transport protocol RTP.

The stateless protocol is a protocol where a server (source device) saves no information about the state of a client (sink device) when the server sends a request file to the client. Hence, although the client provided information to the server in a previous connection, once the connection is terminated the client should send the information to the server again even if the server requests the same information.

The sink device 330, as a device to consume and to render content, performs necessary operations by receiving commands from the control point 310. In particular, according to an exemplary embodiment of the present invention, the sink device 330 uses a HTTP command when sending a control command for receiving AV content from the source device 320 using a connectionless protocol such as the real-time transport protocol RTP. That is, when receiving a play command from the control point 310, the sink device 330 sends the play command to the source device 320 using HTTP.

The sink device 330 receives the AV content from the source device 320 using RTP and then renders the received content.

RTP is a connectionless protocol. In a connectionless protocol, data is sent without a connection being established. As a result, successful transfer of data is not confirmed. In contrast, in a connection-oriented protocol a connection is created between a sender and receiver prior to the data being sent. The data flows on an established connection, thereby generating successful data delivery.

In the following, configurations of the source device 320 and the sink device 330 will be described in detail.

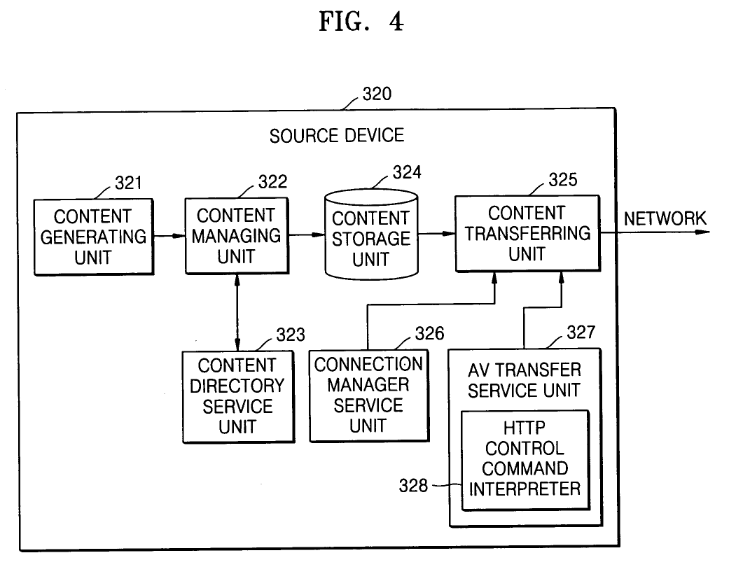

FIG. 4 is a block diagram showing a configuration of the source device according to an exemplary embodiment of the present invention.

Referring to FIG. 4, the source device includes a content generating unit 321, a content managing unit 322, a content directory service unit 323, a content storage unit 324, a content transferring unit 325, a connection manager service unit 326 and an AV transfer service unit 327.

The content generating unit 321 generates AV content by capture.

The content managing unit 322 manages content generated by the content generating unit 321.

The content storage unit 324 is a database to store the content.

The content transferring unit 325 transfers the content from the storage unit 324 to the sink device over a network.

The content directory service unit 323 provides a service that includes a directory of usable content such as videos, music, and pictures. Browse is an important function included in this service. Browse allows the control point to obtain detailed information about the content the source device can provide. The detailed information includes transport protocol information and data format information, which are supported by specific content.

The connection manager service unit 326 determines how content will be transferred from media servers to medial renders.

An AV transfer service unit 327 controls flow of content, such as play, stop, pause, seek, and so on. In particular, according to an exemplary embodiment of the present invention, the AV transfer service unit 327 includes an HTTP control command interpreter 328 to interpret an HTTP control command received from the sink device. Under an exemplary embodiment of the present invention, the HTTP control command requires the sink device to receive or control content using RTP. The HTTP control command interpreter 328 receives and interprets the IWYP control command. AV transfer service unit 327 controls the content to be transferred to the sink device.

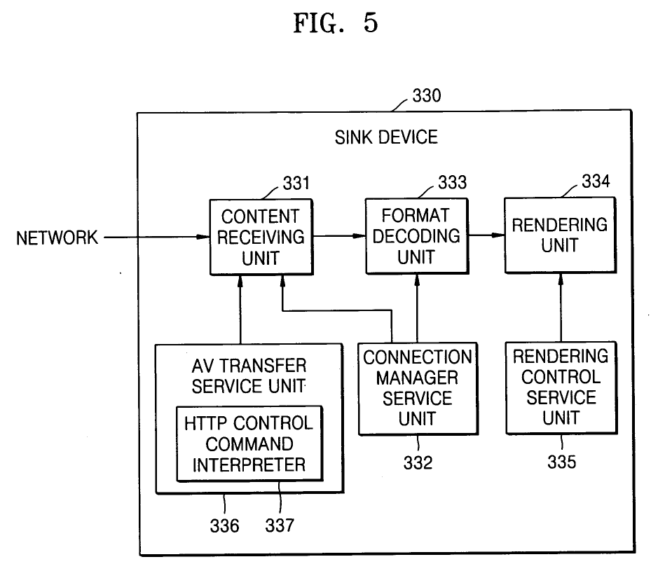

FIG. 5 is a block diagram of a configuration of a sink device according to an exemplary embodiment of the present invention.

Referring to FIG. 5, the sink device 330 includes a content receiving unit 331, connection manager service unit 332, a format decoding unit 333, a rendering unit 334, a rendering control service unit 335, and an AV transfer service unit 336. The content receiving unit 331 receives content from the source device over a network. The format decoding unit 333 decodes the content received by the content receiving unit 331. The rendering unit 334 renders the data decoded by the format decoding unit 333. The connection manager service unit 332 manages the connections with devices.

The rendering control service unit 335 controls how the content will be played and may also render features of the content such as volume, contrast, and brightness.

An AV transfer service unit 336 controls the flow of content through functions such as play, stop, pause, and seek. In particular, according to an exemplary embodiment of the present invention, the AV transfer service unit 336 includes an HTTP control command generator 437 generating an HTTP control command that instructs the source device to perform an operation when the command for content operation is received from the control point. When the HTTP control command generator 437 generates an HTTP control command, the AV transfer service unit 336 controls the generated HTTP control command, which is to be transferred to the source device.

The content controlling operations, using HTTP (a stateless protocol), and RTP (a connectionless protocol) are described in the following with reference to the units of FIGS. 3 through 5.

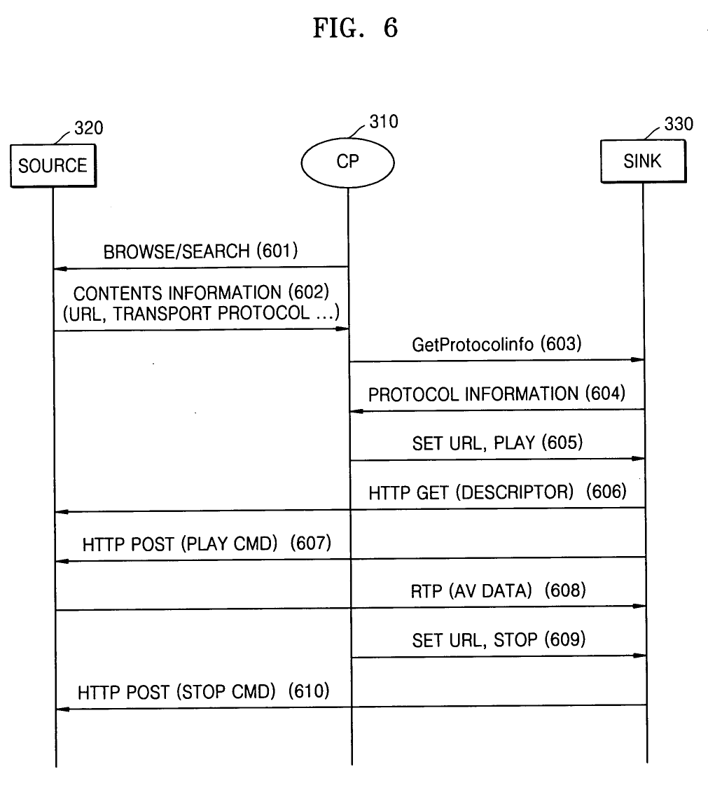

FIG. 6 is a flowchart of a normal play/stop operation according to an exemplary embodiment of the present invention. Referring to FIG. 6, the control point 310 executes a browse or search command for obtaining information about the content from the source device 320 (Operation 601). The control point 310 obtains the transport protocol information, the URL of the content and information about the transport system (Operation 602).

Thereafter, the control point 310 transmits a “Getprotocolinfo” command to the sink device 330 (Operation 603) to obtain the transport protocol information that the sink device can support (Operation 604). The control point 310 receives the transport protocol information from the sink device and determines which transport protocol matches with a transport protocol supported by the source device 320.

Next, the control point 310 provides the sink device 330 with protocol information and a content URL together with a play command in order to play the content (Operation 605).

It is not illustrated, but the sink device 330 receives the play command from the control point 310 and gets AV content from the source device 320 by using an HTTP GET method, when the protocol used is HTTP.

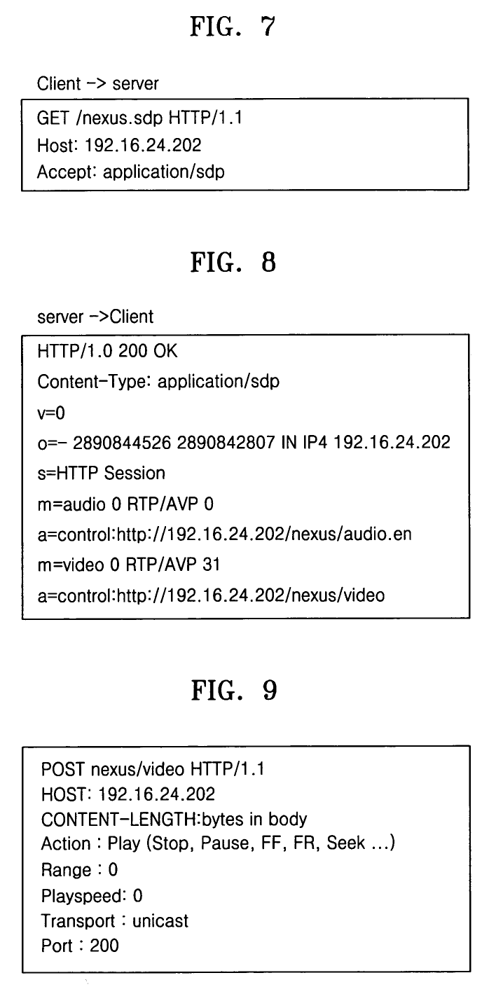

Alternatively, when the protocol to be used is RTP, the sink device reads a descriptor from a corresponding URL by using an HTTP GET method (Operation 606). This operation can be performed using the HTTP GET command illustrated in FIG. 7 and the corresponding response command illustrated in FIG. 8.

Referring to FIG. 7, in the HTTP GET command the sink device 330 requests a content descriptor, “/nexus.sdp”, from the source device 320.

Referring to FIG. 8, the response command includes the descriptor requested by the sink device 330. The ‘v’ denotes a protocol version, the ‘o’ indicates <username> <session id> <version> <network type> <address type> <address>, the ‘s’ denotes a session name, the ‘m’ specifies a media name and transport address, and the ‘a’ is a list of zero or more media attribute lines. The URL http://192.16.24.202/nexus/audio.en is for controlling audio media, and the URL http://192.16.24.202/nexus/video is for controlling video media. Further, the ‘m’ field of the descriptor specifies that audio and video is transmitted using RTP/AVP.

In this exemplary embodiment, when only video is requested, the sink device 330 sends necessary information by using an HTTP POST command as illustrated in FIG. 9 (Operation 607).

Referring to FIG. 9, the first line of a HTTP POST message is a request line composed of POST as a method, “nexus/video” as a control URL, and “HTTP/1.1” as an HTTP version.

In the ‘HOST’ line, “192.16.24.202” is the host of the control URL and ‘bytes in body’ as a ‘CONTENT-LENGTH’ which is a size of body are indicated.

The ‘action’ is a control operation, and can include stop, pause, fast forward, fast rewind, seek, in addition to the “play” shown in FIG. 9.

‘Range’ signifies a range of playback time. ‘Playspeed’ indicates the speed of playing the content. ‘Transport’ denotes the transport protocol to be used to send content, and the transport protocol can be “multicast”. However, in FIG. 9, “unicast” is requested when RTP is used.

The ‘port’ indicates a port address to which content is sent, and here “200” refers to port 200. Information about the port may be provided by the source device (server) by SDP (session description protocol), specified by the sink device (client) as illustrated in FIG. 9, or may be a value provided from the control point. SDP is a protocol intended for describing multimedia sessions for purposes of a session announcement, session invitation, and other forms of multimedia session initialization.

The source device 320 receiving the control command sends the specified content to the port requested by the client (sink device 330) using RTP (Operation 608). The sink device 330 receives and processes the content sent to the RTP port.

When stopping the playback of content, the control point 310 provides the sink device 330 with protocol information and a content URL that is sent together with a stop command (Operation 609).

The sink device 330 transmits a stop command to the source device 320 by using an HTTP control command. For example, an HTTP POST command (Operation 610).

In the operation illustrated in FIG. 6, the control point can coexist with the source device or the sink device in one device, and in this case, the interaction between the control point and each device is unnecessary.

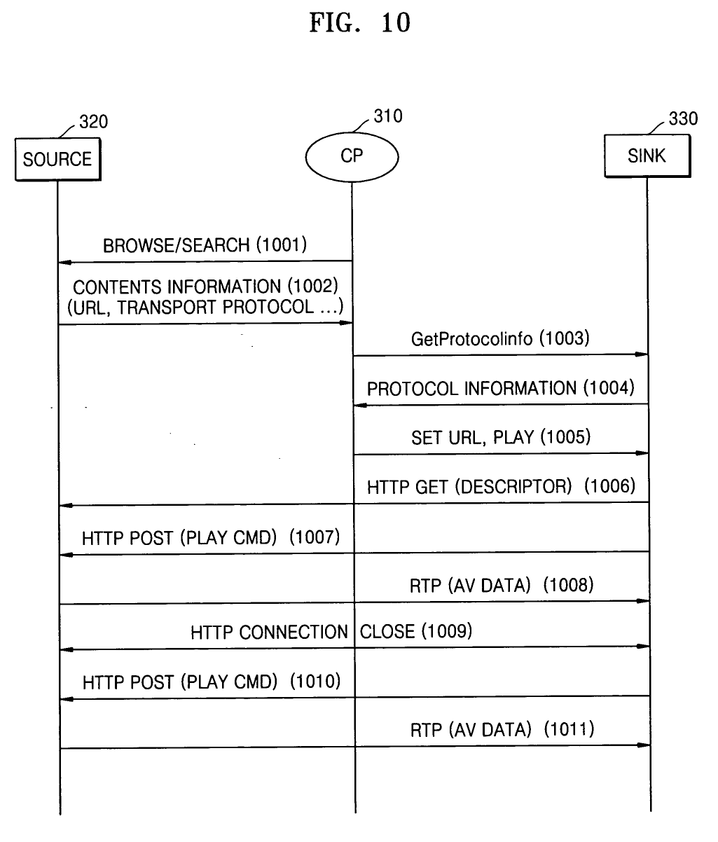

To stop the AV data streaming the sink device transmits an HTTP POST STOP command to the source device. It does so by receiving a stop command and a corresponding URL from the control point, or a TCP connection for sending commands is disconnected. An example when the transmission is interrupted by TCP disconnection is illustrated in FIG. 10.

Specifically, according to an exemplary embodiment of the present invention, FIG. 10 is a flowchart for explaining operations of stopping RTP transmission when TCP disconnection occurs.

Referring to FIG. 10, the control point 310 executes a browse or search command (Operation 1001), receives a content URL and the transport protocol information from the source device (Operation 1002). Next the control point 310 sends a “Getprotocolinfo” command to the sink device 330 (Operation 1003), receives a listing of the transport protocols the sink device can support (Operation 1004), and sequentially provides the sink device 330 with the protocol information and a content URL that will be sent together with a play command (Operation 1005). The sink device 330 receives the play command from the control point 310, and then reads a descriptor from a corresponding URL using an HTTP get (when the data transfer protocol is RTP) (Operation 1006). Then, through RTP the source device 320 transmits the specified content to a port requested by the sink device 330 (Operation 1008). These operations are the same as those of FIG! 6.

While transmitting AV data using RTP, if the HTTP connection between the source device 320 and the sink device 330 is lost (Operation 1009), the corresponding RTP transmission is stopped. There are several possible ways the HTTP connection between the source device and the sink device may be released. Generally, hardware and software errors cause the connection to be lost.

Since HTTP is a stateless protocol, when the connection is lost the source device does not have state information about the play command previously received in operation 1007. Thus, when the sink device 330 intends to play the AV content, the sink device 330 sends the HTTP POST PLAY command again to the source device 320 (Operation 1010). Then, the source device 320 transmits through RTP the requested AV data to the sink device 330 (Operation 1011).

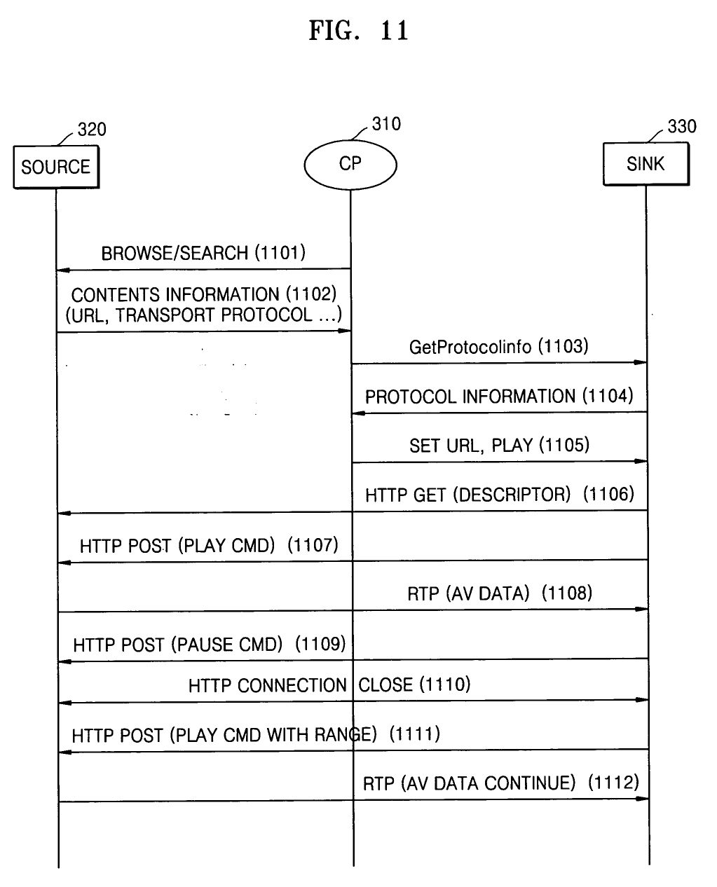

FIG. 11 is flowchart which includes an operation of stopping RTP transmission by an HTTP PAUSE command according to an exemplary embodiment of the present invention.

Referring to FIG. 11, Referring to FIG. 10, the control point 310 executes a browse or search command (Operation 1101), receives a content URL and the transport protocol information from the source device (Operation 1102). Next the control point 310 sends a “Getprotocolinfo” command to the sink device 330 (Operation 1103), receives a listing of the transport protocols the sink device can support (Operation 1104), and sequentially provides the sink device 330 with the protocol information and a content URL that will be sent together with a play command (Operation 1105). The sink device 330 receives the play command from the control point 310, and then reads a descriptor from a corresponding URL using an HTTP get (when the data transfer protocol is RTP) (Operation 1106). Then, through RTP the source device 320 transmits the specified content to a port requested by the sink device 330 (Operation 1108). These operations are the same as those of FIG. 6.

If during AV data transmission through RTP, the sink device 330 sends an HTTP POST PAUSE command to the source device 320 (Operation 1109), data transmission is stopped. Here, if the HTTP connection is maintained between the source device 320 and the sink device 330, the sink device 330 can resume the RTP transmission by sending a HTTP POST RESUME commend to the source device 320.

However, when the HTTP connection is disconnected before resumption (Operation 1110), the resume command produces the same effect as the HTTP POST STOP command. Accordingly, RTP transmission is stopped. In other words, the disconnection of a stateless protocol such as HTTP, affects operations of a connectionless protocol such as RTP. Hence, the sink device 330 sends an HTTP POST PLAY command having a range header, which denotes a range of the previously transmitted AV content the sink device 330 requests, to the source device 320 (Operation 1111). The source device 320 is able to transmit the corresponding AV content to the sink device 330 (Operation 1112), and the results is a resumption of data transmission.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over a network of computer systems so that the computer readable code is stored and executed in a distributed fashion. Also, functional programs, codes, and code segments for accomplishing the present invention can be easily created by programmers skilled in the art to which the present invention pertains.

As described above, according to an exemplary embodiment of the present invention, when AV content is transmitted through RTP over a network, the content is controlled by a stateless protocol such as HTTP instead of a state protocol such as RTSP. Thus, RTP is easily supported by an effective content control method.

While the present invention has been particularly shown and described with reference to exemplary embodiments thereof, it will be understood by those of ordinary skill in the art that various changes in form and details may be made therein without departing from the spirit and scope of the present invention as defined by the following claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

1. A method of controlling content over a network comprising:
generating a control command using a stateless protocol so that an AV content providing device controls transmission of an AV content using a connectionless protocol;
and transmitting the generated control command to the AV content providing device.

2. The method of claim 1, wherein a real-time transport protocol (RTP) is used as the connectionless protocol, and a hypertext transfer protocol (HTTP) is used as the stateless protocol.

3. The method of claim 1, wherein the control command using the stateless protocol includes information about a port to which the AV content is sent using the connectionless protocol.

4. The method of claim 1, wherein the control command using the stateless protocol includes information about a transport system in which the AV content is transmitted using the connectionless protocol.

5. The method of claim 4, wherein the transport system includes one of unicast and multicast.

6. The method of claim 1, wherein release of a connection based on the stateless protocol stops the transmission of the AV content using the connectionless protocol.

7. A method for providing content over a network comprising:
receiving a control command using a stateless protocol from an AV content controlling device in order to control transmission of an AV content; and
transmitting the AV content to the AV content controlling device by using a connectionless protocol in response to the control command.

8. The method of claim 7, wherein an RTP is used as the connectionless protocol, and an HTTP is used as the stateless protocol.

9. The method of claim 7, wherein the control command using the stateless protocol includes information about a port to which the AV content is sent using the connectionless protocol.

10. The method of claim 7, wherein the control command using the stateless protocol includes information about a transport system in which the AV content is transmitted using the connectionless protocol.

11. The method of claim 10, wherein the transport system includes one of unicast and multicast.

12. The method of claim 7, wherein release of connection based on the stateless protocol stops the AV content transmission using the connectionless protocol.

13. A device for controlling content over a network comprising:
an AV content providing device; and
an AV transmitting service unit generating a control command using a stateless protocol and transmitting the generated control command so that the AV content providing device can control an AV content transmission.

14. The device of claim 13, wherein an RTP is used as the connectionless protocol, and an HTTP is used as the stateless protocol.

15. The device of claim 13, wherein the control command using the stateless protocol includes information about a port to which the AV content is sent using the connectionless protocol.

16. The device of claim 13, wherein the control command using the stateless protocol includes information about a transport system in which the AV content is transmitted using the connectionless protocol.

17. The device of claim 16, wherein the transport system includes one of unicast and multicast.

18. The device of claim 13, wherein release of a connection based on the stateless protocol stops the AV content transmission using the connectionless protocol.

19. A device for providing content over a network comprising:
an AV content controlling device that controls transmission of an AV content;
an AV transmitting service unit receiving a control command using a stateless protocol from the AV content controlling device, and interpreting the received control command; and
a transferring unit sending the AV content to the AV content controlling device based on the interpreted information using a connectionless protocol.

20. The device of claim 19, wherein a RTP is used as the connectionless protocol, and a HTTP is used as the stateless protocol.

21. The device of claim 19, wherein the control command using the stateless protocol includes information about a port to which the AV content is sent using the connectionless protocol.

22. The device of claim 19, wherein the control command using the stateless protocol includes information about a transport system in which the AV content is transmitted using the connectionless protocol.

23. The device of claim 22, wherein the transport system includes one of unicast and multicast.

24. The device of claim 19, wherein release of connection based on the stateless protocol stops the transmission of the AV content using the connectionless protocol.
